(19) United States
(12) Patent Application Publication
(10) Pub. No.: US 2007/0059922 A1
(43) Pub. Date: Mar. 15, 2007

(54) Post-etch removal of fluorocarbon-based residues from a hybrid dielectric structure

(75) Inventors: Lawrence A. Clevenger, LaGrangeville, NY (US); Andrew P. Cowley, Wappingers Falls, NY (US); Timothy J. Dalton, Ridgefield, CT (US); Mark Hoinkis, Fishkill, NY (US); Kaushik A. Kumar, Beacon, NY (US); Douglas C. La Tulipe JR., New Fairfield, CT (US); David L. Rath, Stormville, NY (US); Chih-Chao Yang, Poughkeepsie, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, ARMONK, NY (US)

(21) Appl. No.: 11/162,511

(22) Filed: Sep. 13, 2005

(51) Int. Cl. H01L 21/4763

(52) U.S. Cl. 438/637

(57) ABSTRACT

The present invention relates to methods for post-etch, particularly post-RIE, removal of fluorocarbon-based residues from a hybrid dielectric structure. The hybrid dielectric structure contains a first dielectric material, and a line-level dielectric layer containing a second, different dielectric material, and wherein said second, different dielectric material comprises a polymeric thermoset dielectric material having a dielectric constant less than 4. Low energy electron beam or low temperature annealing is utilized by the present invention for removal of the fluorocarbon-based residues from such a hybrid dielectric structure, without damaging the low-k polymeric thermoset dielectric material contained in such a hybrid dielectric structure.

### FIELD OF THE INVENTION

The present invention relates generally to the manufacture of high-speed semiconductor microprocessors, application specific integrated circuits (ASICs), and other high-speed integrated circuit (IC) devices. More particularly, this invention relates to methods for removing fluorocarbon-based residues from an advanced back-end-of-line (BEOL) interconnect structure that contains a hybrid dielectric stack with low-k dielectric materials after a dual damascene etching process.

### BACKGROUND OF THE INVENTION

Metal interconnections in very large scale integrated (VLSI) or ultra-large integrated (ULSI) circuits typically consist of interconnect structures containing patterned layers of metal wiring. Typical integrated circuit (IC) devices contain from three to fifteen layers of metal wiring. As feature size decreases and device area density increases, the number of interconnect layers is expected to increase.

The materials and layout of these interconnect structures are preferably chosen to minimize signal propagation delays, hence maximizing the overall circuit speed. An indication of signal propagation delay within the interconnect structure is the RC time constant for each metal wiring layer, where R is the resistance of the wiring and C is the effective capacitance between a selected signal line (i.e., conductor) and the surrounding conductors in the multilevel interconnect structure. On one hand, the RC time constant may be reduced by lowering the resistance of the wiring material. Copper is therefore a preferred material for IC interconnects due to its relatively low resistance. On the other hand, the RC time constant may also be reduced by using dielectric materials that have a low dielectric constant k, because low-k dielectrics reduce the parasitic capacitance between the metal lines. To obtain a sufficiently low RC time constant, a low-k dielectric material (with k<4) is preferred.

These new materials are typically employed in a fabrication process commonly referred to as “Dual Damascene,” which is used to create the multi-level, high density metal interconnect structures needed for advanced, high performance ICs. The initial transition to Dual Damascene employed copper metal with a conventional silicon dioxide dielectric. More recently, the trend has moved towards the replacement of the silicon dioxide dielectric with new low-k dielectric materials.

State-of-the-art Dual Damascene interconnect structures comprising both copper interconnects and low-k dielectric materials are described by R.D. Goldblatt et al. in “A High Performance 0.13 μm Copper BEOL Technology with Low-K Dielectric,” PROCEEDINGS OF THE IEEE 2000 INTERNATIONAL INTERCONNECT TECHNOLOGY CONFERENCE, pp. 261-263 (2000). A typical interconnect structure using low-k dielectric material and copper interconnects is shown in FIG. 1. The interconnect structure comprises a lower substrate 10 which may contain logic circuit elements, such as transistors. An optional cap layer 11 may be disposed above the lower substrate 10. A dielectric layer 12, commonly known as an inter-layer dielectric (ILD), overlies the substrate 10 and the optional cap layer 11. In advanced interconnect structures, ILD layer 12 is preferably a low-k polymeric thermoset material such as SiLK™ (an aromatic hydrocarbon thermosetting polymeric dielectric material available from the Dow Chemical Company, which has a dielectric constant of about 2.65). A hardmask layer 17 of, e.g., silicon nitride may be disposed on ILD layer 12. Conductors 14, 18 (via and trench, respectively) are embedded in the ILD layer 12. Conductors 14, 18 are typically copper in advanced interconnect structures, but may alternatively be aluminum or another conductor material. A diffusion barrier liner (not shown) may be disposed between ILD layer 12 and the conductors 14, 18. If present, the diffusion barrier liner may be comprised of tantalum, titanium, tungsten or nitrides of these metals. The top surface of conductor 18 is made coplanar with the top surface of cap layer 17, usually by a chemical-mechanical polish (CMP) step. A final cap layer 19, also of, e.g., silicon nitride, may be disposed over the entire structure. In the drawing, the conductor 14 is referred as a via, while the conductor 18 is referred as a line (or a trench). The line (or trench) typically has a greater width than the via.

However, copper interconnect structures using low-k materials as the ILD can suffer from reliability problems, including mechanical failure caused by thermal expansion of the low-k dielectric materials. For example, the coefficient of thermal expansion (CTE) of SiLK™ dielectric is greater than 80 ppm/° C., while the CTE of silicon dioxide is approximately 15 ppm/° C. Additionally, the CTE of Cu is approximately 18 ppm/° C. This difference has been shown to significantly contribute to such reliability problems. Due to the small via cross-sectional area, the mismatch in the CTE can result in shearing of the via.

U.S. Patent Application Publication No. 2005/0023693, as published on Feb. 3, 2005 for “Reliable Low-K Interconnect Structure with Hybrid Dielectric,” therefore proposed to solve the reliability problems associated with the difference between the CTE for the polymeric low-k dielectric, such as SiLK™, and the CTE for Copper, by providing a hybrid dielectric structure that comprises two different inter-layer dielectric (ILD) materials, one for the via level and the other for the line (or trench) level. The via-level ILD material is preferably a low-k dielectric material having a low coefficient of thermal expansion (CTE), such as SiCOH (e.g., a silicon doped oxide) or an oxide dielectric material, for the purpose of increasing reliability, while the line-level ILD material is preferably a low-k polymeric thermoset dielectric material, such as SiLK™. It is particularly preferred that the via-level ILD material comprises a dielectric material having a CTE of less than about 30 ppm/° C., and preferably to match the CTE of the via-level conductors.

The via and trench (or line) are fabricated in such a hybrid dielectric structure by lithography patterning and an etching process that includes reactive ion etching (RIE). The RIE process typically utilizes fluorinated gases for etching inorganic materials. Further, various polymeric additives are employed during the RIE process for better etch selectivity and better etch profile control.

Fluorinated gases, however, tend to cause polymerization of the additives and formation of fluorocarbon-based polymeric residues on the wafer surface. Such fluorocarbon-based polymeric residues are yield suppressors that cause low production yield. Further, such polymeric residues tend to swell in presence of humidity in the ambient environment and can lead to reliability problems.

Removal of such polymeric residues from the hybrid dielectric structure poses a particular challenge, because conventional cleaning or residue-removal techniques, although suitable for use with conventional low-k dielectric materials, such as SiCOH or oxide dielectric materials, may damage the low-k polymeric thermoset dielectric materials, such as SiLK™.

Therefore, there is a need for methods that can be used to effectively remove the fluorocarbon-based polymeric residues from the hybrid dielectric structure after the RIE process, without damaging the low-k polymeric thermoset dielectric materials.

### SUMMARY OF THE INVENTION

The present invention in one aspect relates to a method for at least partially removing fluorocarbon-based polymeric residues, typically generated during via and/or trench etching processes such as a RIE process, from a hybrid dielectric structure that comprises a via-level dielectric layer containing a first dielectric material having a dielectric constant k of less than about 4 and a coefficient of thermal expansion (CTE) less than about 30 ppm/° C., and a line-level dielectric layer containing a second, different dielectric material having a dielectric constant k of less than about 4, wherein said second, different dielectric material comprises a polymeric thermoset dielectric material. Specifically, the method comprises: (1) exposing the hybrid dielectric structure to an electron beam created with at least one of an accelerating voltage of less than about 5 KeV and a current electron density of less than about 200 μC/cm², (2) annealing the hybrid dielectric structure at an elevated temperature of less than about 400° C., or (3) a combination of (1) and (2).

It was a surprising and unexpected discovery of the present invention that the fluorocarbon-based polymeric residues are volatile, and the low energy electron beam and/or the low temperature annealing as described hereinabove was sufficient to vaporize and thereby remove such fluorocarbon-based polymeric residues from the hybrid dielectric structure, without damaging the low-k polymeric thermoset dielectric material contained in the line-level dielectric layer of the hybrid dielectric structure.

In another aspect, the present invention relates to a method comprising:

providing a hybrid dielectric structure as described hereinabove;

etching the hybrid dielectric structure using reactive ion etching, during which fluorocarbon-based polymeric residues is generated; and

exposing the hybrid dielectric structure to an electron beam for at least partial removal of the fluorocarbon-based polymeric residues therefrom.

Preferably, the electron beam employed in the present invention has an accelerating voltage of less than about 5 KeV and/or a current electron density of less than about 200 μC/cm².

In a further aspect, the present invention relates to a method comprising:

providing a hybrid dielectric structure as described hereinabove;

etching the hybrid dielectric structure using reactive ion etching, during which fluorocarbon-based polymeric residues is generated; and

annealing the hybrid dielectric structure at an elevated temperature that is lower than the glass transition temperature of the low-k polymeric thermoset dielectric material contained in the hybrid dielectric structure, for at least partial removal of the fluorocarbon-based polymeric residues.

Preferably, the annealing employed in the present invention is conducted at a temperature less than about 400° C.

Other aspects, features and advantages of the invention will be more fully apparent from the ensuing disclosure and appended claims.

### BRIEF DESCRIPTION OF THE DRAWINGS

FIG. 1 illustratively shows a prior art Dual Damascene interconnect structure that contains low-k dielectric material and copper interconnects.

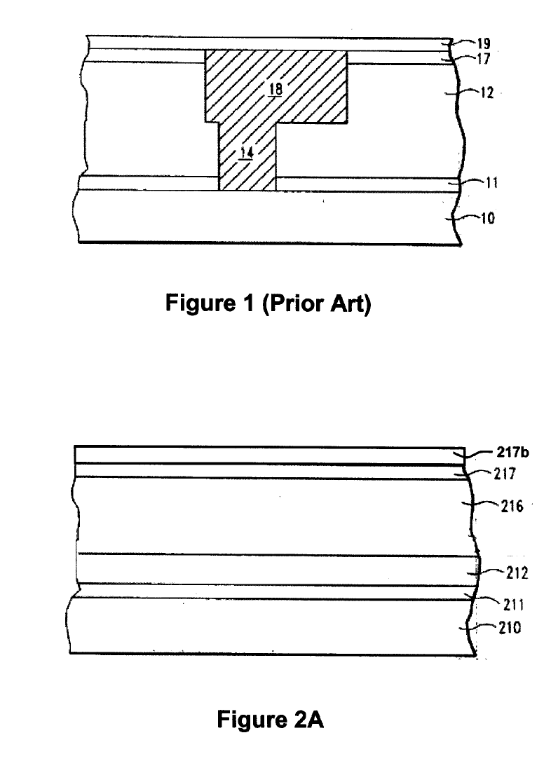

FIGS. 2A-2D illustrates a Dual Damascene process for fabricating a hybrid dielectric structure containing two different low-k dielectric materials.

FIGS. 3A-3C shows post-RIE residue removal of a hybrid dielectric structure by exposure to a low energy electron beam, according to one embodiment of the present invention.

FIGS. 4A-4B shows post-RIE residue removal of a hybrid dielectric structure by exposure to low temperature annealing, according to one embodiment of the present invention.

### DETAILED DESCRIPTION OF THE INVENTION

U.S. Patent Application Publication No. 2005/0023693 published on Feb. 3, 2005 for “RELIABLE LOW-K INTERCONNECT STRUCTURE WITH HYBRID DIELECTRIC” is incorporated herein by reference in its entirety for all purposes.

In the following description, numerous specific details are set forth, such as particular structures, components, materials, dimensions, processing steps and techniques, in order to provide a thorough understanding of the invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

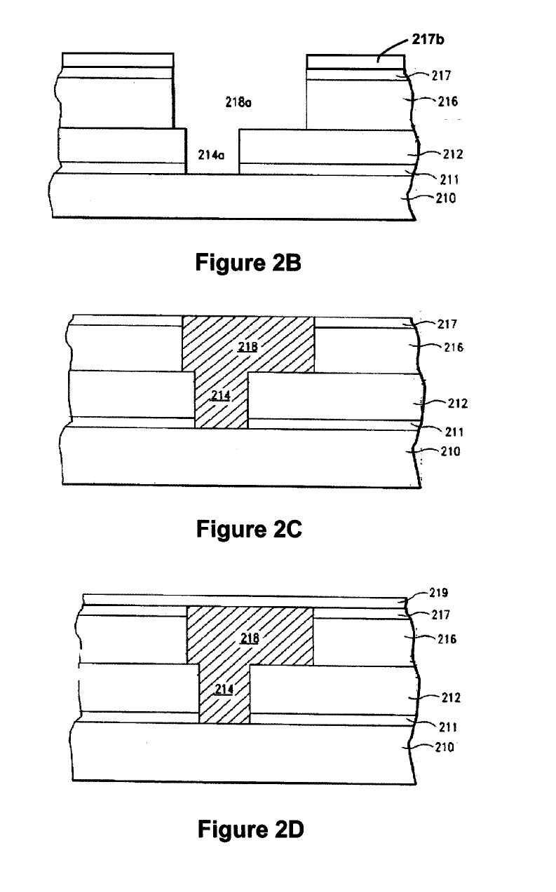

FIGS. 2A-2D briefly illustrate a Dual Damascene process for forming a hybrid dielectric structure containing two different low-k dielectric materials for the via-level dielectric layer and the line-level dielectric layer.

Such Dual Damascene process optionally begins with deposition of a cap layer 211 on a semiconductor substrate 210, followed by deposition of a first ILD layer 212 on the cap layer 211. After the deposition of the first ILD layer, a second ILD layer 216 and a hard mask layer stack 217 and 217(b) are deposited. Then, trench 218a and via 214a are formed, as shown in FIG. 2(b), using conventional lithography patterning and an etching process that includes reactive ion etching (RIE) steps. After line level lithography is performed, the etching process transfers the line level pattern onto the hard-mask levels 217(b), selective to the non-sacrificial hard mask layer 217. Lithography is then performed to pattern the via level. The etching process transfers the via pattern by removing the second ILD layer 216, selectively stopping on ILD layer 212. Next, the remaining line-level hard mask layers (including layer 217) are etched selective to hardmask 217(b). The etch process continues by etching the via 214a pattern onto layer 212, and selectively stopping the via on layer 211 and the trench on layer 212. Next, the cap layer 211 is etched to complete the via. In some embodiments, the cap layer 211 is not etched to provide a via that is not open. Via 214a and trench 218a are then filled with conductive material which can be the same or different to form conductors 214, 218, as shown in FIG. 2C. Excess conductor material may be removed in a chemical mechanical polishing (CMP) process. After conductors 214 and 218 are formed, a final cap layer 219 may be deposited as shown in FIG. 2D.

The first and second ILD layers 212 and 216 may be formed of any suitable dielectric material, although low-k dielectric materials are preferred. Suitable dielectric materials include, but are not limited to: carbon-doped silicon dioxide materials; fluorinated silicate glass (FSG); organic polymeric thermoset materials, silicon oxycarbide; SiCOH dielectrics; fluorine doped silicon oxide; spin-on glasses; silsesquioxanes, including hydrogen silsesquioxane (HSQ), methyl silsesquioxane (MSQ), and mixtures or copolymers of HSQ and MSQ; benzocyclobutene (BCB)-based polymer dielectrics, and any silicon-containing low-k dielectric. Examples of spin-on low-k films with SiCOH-type composition using silsesquioxane chemistry include HOSP™ (available from Honeywell), JSR 5109, 5525, 5530, etc., (available from Japan Synthetic Rubber), Zirkon™ (available from Shipley Microelectronics, a division of Rohm and Haas), and porous low-k (ELk) materials (available from Applied Materials). Examples of carbon-doped silicon dioxide materials, or organosilanes, include Black Diamond™ (available from Applied Materials) and Coral™ (available from Novellus). An example of an HSQ material is FOx™ (available from Dow Corning). Preferred dielectric materials include organic polymeric thermoset materials, consisting essentially of carbon, oxygen, and hydrogen, including the low-k polyarylene ether polymeric material known as SiLK™ (available from the Dow Chemical Company), and the low-k polymeric material known as FLARE™ (available from Honeywell).

Preferably, the via-level ILD layer 212 is formed of a material having a low coefficient of thermal expansion (CTE), such as SiCOH or oxide dielectric material to improve reliability, and the line-level ILD layer 216 is formed of a polymeric thermoset material having a low k, such as SiLK™. It is particularly preferred that via-level ILD layer 212 is formed of a dielectric material having a CTE of less than about 30 ppm/° C., and preferably to match the CTE of the conductor 214.

Accordingly, the RIE chemistry can be adjusted to increase etching selectivity between the different ILD layers 212 and 216. For example, fluorinated gases, such as CF₄, CHF3, CH2F2, CH3F, C4F8, C4F6, C5F8, NF3, etc., can be used to etch the inorganic SiCOH materials, while N₂H₂, N2/O2, Ar/O2 gases may be used to etch the polymeric thermosetting materials such as SiLK™.

However, as mentioned previously, the RIE process typically employs organic additives to enhance the etch selectivity and etch profile control. Moreover, the fluorinated gases used for etching the inorganic SiCOH materials may cause polymerization of the organic additives and formation of fluorocarbon-based polymeric residues on the wafer surface, which have detrimental impact on the performance of the resulting device structure.

In order to effectively remove such fluorocarbon-based polymeric residues generated during the RIE process from the hybrid dielectric structure without damaging the low-k polymeric thermoset dielectric materials, the present invention utilizes low energy electron beam evaporation or low temperature annealing steps for post-RIE cleaning of the hybrid dielectric structure.

In one embodiment of the present invention, the hybrid dielectric structure containing RIE-generated fluorocarbon-based residues is exposed to an electron flux, e.g., an electron beam, which is sufficient for vaporizing and removing such residues. For example, a focused electron beam can be used to raster on areas of interest. Alternatively, an unfocused electron beam can be used to impinge on the areas of interest, without rastering. The acceleration voltage and the current electron density and of the electron beam is limited, so that the total energy of the electron beam is sufficiently low and will not induce damage to the low low-k polymeric thermoset dielectric material contained in the hybrid dielectric structure. For example, the acceleration voltage of the electron beam is preferably less than 5 KeV, more preferably from about 1 KeV to about 3 KeV, and most preferably about 2 KeV. The current electron density of the electron beam is preferably less than 200 μC/cm², more preferably from about 50 μC/cm² to about 150 μC/cm² , and most preferably about 100 μC/cm². Preferably, exposure of the hybrid dielectric structure to the electron beam lasts for from about 10 seconds to about 100 seconds, and more preferably from about 20 seconds to about 60 seconds.

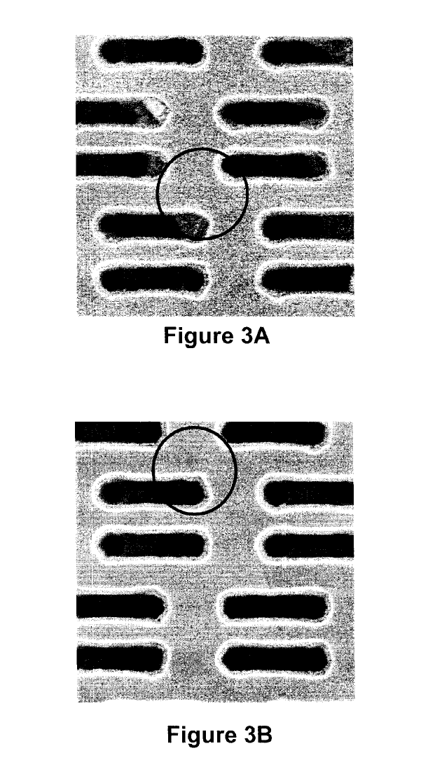

FIG. 3A shows a top view of a hybrid dielectric structure, which contains via openings 310 formed by a reactive ion etching (RIE) process. Fluorocarbon-based polymeric residues have been formed during the RIE process, which cover a top surface of the hybrid dielectric structure and partially block one of the via openings, as indicated by the black line circle in FIG. 3A. Post-RIE exposure of the hybrid dielectric structure to a low energy electron beam having an acceleration voltage of about 2 KeV and a current electron density of about 100 μC/cm² for about 5 seconds partially vaporizes and removes the fluorocarbon-based polymeric residues, as shown in FIG. 3B. Extended exposure to such a low energy electron beam for about 30 seconds completely vaporizes and removes the residues, as shown in FIG. 3C.

The electron-beam-based post-etch residue removal method as described by the present invention avoids usage of any high energy ions that are typically employed in conventional post-etch residue removal methods. The high energy ions can sputter the chamber walls, cause damage to the dielectric materials, and form unwanted driven-in mobile ions within the semiconductor device structure. Therefore, by avoiding usage of the high energy ions, the present invention achieves residue removal without sputtering of the chamber walls, damaging the dielectric materials, or inducing mobile ion drive-in. Further, the present invention effectively removes the fluorocarbon-based residues without use of any chemical agents and is thus environmental friendly.

In another embodiment of the present invention, the hybrid dielectric structure containing RIE-generated fluorocarbon-based residues is annealed at an elevated temperature lower than the glass transition temperature (Tg) of the low-k polymeric thermosetting dielectric material contained in the hybrid dielectric structure. Preferably, the annealing temperature is less than 400° C. and more preferably ranges from about 100° C. to about 400° C. Preferably, annealing of the hybrid dielectric structure lasts for from about 1 minute to about 60 minutes, and more preferably from about 10 minutes to about 30 minutes.

Such a low temperature annealing process is compatible with the low-k polymeric thermosetting dielectric material, i.e., it is close to the curing temperature typically employed for curing the low-k polymeric thermosetting dielectric material and therefore will not cause any damage to such polymeric dielectric material. More importantly, due to the high volatility of the fluorocarbon-based residues, low temperature annealing as described herein is sufficient for removal of such residues.

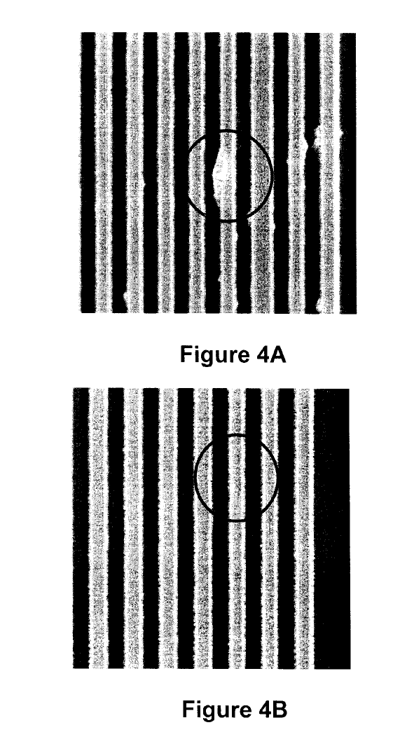

FIG. 4A shows a top view of a hybrid dielectric structure, which contains interconnect patterns formed by a reactive ion etching (RIE) process. Fluorocarbon-based polymeric residues have been formed during the RIE process and cover a top surface of the hybrid dielectric structure, as indicated by the circle in FIG. 4A. Post-RIE annealing of the hybrid dielectric structure at a relatively low annealing temperature of about 400° C. for about 30 minutes effectively vaporizes and removes the fluorocarbon-based polymeric residues, as shown in FIG. 4B.

The low energy electron beam or the low temperature annealing can be either independently or jointly employed for post-RIE residue removal in the present invention.

It should be noted that although the above description is directed primarily to a hybrid dielectric structure containing low-k polymeric thermosetting dielectric material, it is understood that the methods of the present invention can be readily applied for removing fluorocarbon-based polymeric residues from any other semiconductor structure that contains low-k dielectric material(s).

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method for at least partially removing fluorocarbon-based polymeric residues from a hybrid dielectric structure, comprising one of:
(a) exposing said hybrid dielectric structure to an electron beam that is created with at least one of an accelerating voltage of less than about 5 KeV and a current electron density of less than about 200 μC/cm², to remove at least a portion of the fluorocarbon-based polymeric residues contained by said hybrid dielectric structure;
(b) annealing the hybrid dielectric structure at an elevated temperature of less than about 400° C., to remove at least a portion of the fluorocarbon-based polymeric residues contained by said hybrid dielectric structure; or
(c) a combination of (a) and (b),
wherein the hybrid dielectric structure comprises a via-level dielectric layer containing a first dielectric material, and a line-level dielectric layer containing a second, different dielectric material, and wherein said second, different dielectric material comprises a polymeric thermoset dielectric material having a dielectric constant less than 4.

2. The method of claim 1, wherein the first dielectric material has a coefficient of thermal expansion (CTE) less than about 30 ppm/° C.

3. The method of claim 2, wherein the first dielectric material further has a dielectric constant less than about 4.

4. The method of claim 1, wherein the first dielectric material comprises SiCOH.

5. The method of claim 1, wherein the electron beam is created at an accelerating voltage from about 1 KeV to about 3 KeV.

6. The method of claim 1, wherein the hybrid dielectric structure is exposed to an unfocused electron beam.

7. The method of claim 1, wherein the hybrid dielectric structure is rastered by a focused electron beam.

8. The method of claim 1, wherein the hybrid dielectric structure is exposed to the electron beam for from about 20 seconds to about 60 seconds.

9. The method of claim 1, wherein annealing of the hybrid dielectric structure is conducted at an elevated temperature of from about 100° C. to about 400° C.

10. The method of claim 1, wherein the hybrid dielectric structure is annealed for from about 10 minutes to about 30 minutes.

11. A method comprising:
providing a hybrid dielectric structure that comprises a via-level dielectric layer containing a first dielectric material and a line-level dielectric layer containing a second, different dielectric material, wherein said second, different dielectric material comprises a polymeric thermoset dielectric material having a dielectric constant less than 4;
etching the hybrid dielectric structure, during which fluorocarbon-based polymeric residues is generated; and
exposing the hybrid dielectric structure to an electron beam for at least partial removal of the fluorocarbon-based polymeric residues.

12. The method of claim 11, wherein the electron beam is created at an accelerating voltage of less than about 5 KeV and/or with a current electron density of less than about 200 μC/cm².

13. The method of claim 11, wherein the first dielectric material has a coefficient of thermal expansion (CTE) less than about 30 ppm/° C. and a dielectric constant less than about 4.

14. The method of claim 11, wherein the first dielectric material comprises SiCOH.

15. The method of claim 11, wherein the hybrid dielectric structure is exposed to the electron beam for from about 20 seconds to about 60 seconds.

16. A method comprising:
providing a hybrid dielectric structure that comprises a via-level dielectric layer containing a first dielectric material and a line-level dielectric layer containing a second, different dielectric material, wherein said second, different dielectric material comprises a polymeric thermoset dielectric material having a dielectric constant less than 4, and wherein said second, different dielectric material has a glass transition temperature;
etching the hybrid dielectric structure, during which fluorocarbon-based polymeric residues is generated; and
annealing the hybrid dielectric structure at an elevated temperature that is lower than the glass transition temperature of the second, different material, for at least partial removal of the fluorocarbon-based polymeric residues.

17. The method of claim 16, wherein the annealing is conducted at a temperature less than about 400° C.

18. The method of claim 16, wherein the first dielectric material has a coefficient of thermal expansion (CTE) less than about 30 ppm/° C. and a dielectric constant less than about 4.

19. The method of claim 16, wherein the first dielectric material comprises SiCOH.

20. The method of claim 16, wherein the hybrid dielectric structure is annealed for from about 10 minutes to about 30 minutes.
